(19) United States
(12) Patent Application Publication
(10) Pub. No.: US 2024/0365492 A1
(43) Pub. Date: Oct. 31, 2024

(54) MOTOR CONTROL DEVICE FOR DRIVING A CONVEYING DEVICE

(71) Applicant: Murrelektronik GmbH, Oppenweiler (DE)

(72) Inventors: Bernd WASER, Oppenweiler (DE); Ingo WOLFF, Oppenweiler (DE)

(21) Appl. No.: 18/645,642

(22) Filed: Apr. 25, 2024

(30) Foreign Application Priority Data
Apr. 25, 2023 (EP) 23 169 851.5

(51) Int. Cl. H05K 5/02; B65G 43/00; H01R 4/26

(52) U.S. Cl. CPC H05K 5/0247; B65G 43/00; H01R 4/26; H05K 5/0217

(57) ABSTRACT

A motor control device for at least one drive of a conveying device is shown. The motor control device has a low-voltage supply interface for the direct connection of the motor control device to a low-voltage line. Furthermore, the low-voltage device interface is formed by piercing technology so that the connection to the low-voltage line takes place without interruption. A system is furthermore described.

### FIELD OF THE DISCLOSURE

Embodiments of the present disclosure relate to a motor control device for at least one drive of a conveying device. Furthermore, embodiments of the present disclosure relate to a system having a low-voltage line and at least one motor control device for at least one drive of a conveying device.

### BACKGROUND

In the field of intralogistics, drives designed as roller motors are known which are driven via a motor control device, also referred to as motor controller. Usually, these drives are supplied with safety extra-low voltage or low voltage. In particular in conveying devices by means of which objects having a low weight are conveyed, safety extra-low voltages are often used as they are less complex to install. Low-voltage drives are only used if higher powers are required for conveying the objects.

In most cases, the supply line is interrupted when the motor control device is installed, so that it can be routed through the motor control device. This interruption results in additional resistances, namely due to the clamping and routing of the power through the motor control device, as a result of which the maximum extension of the conveying device is severely limited.

It is also known to supply the drives and the motor control device with a rated voltage of 24 Volt direct current (VDC) or 48 Volt direct current (VDC). This however results in that only few drives can be provided on a supply branch so that the number of required lines is accordingly high, which leads to high installation costs. For an extra-low voltage supply of 24 VDC and 30 W drives, this for example results in that only a maximum of 11 or 18 drives with a typical wiring with 1.5 mm² or 2.5 mm² lines can be supplied. As a motor control device can usually drive four drives, a new voltage supply is already required after three to five motor control devices. The larger the conveying device, the more supply branches are required, which can in particular lead to the fact that numerous lines have to be laid in parallel.

The object of the present disclosure is to achieve a large extension of a conveying device, wherein the efforts are to be reduced.

### SUMMARY

According to the present disclosure, the object is achieved by a motor control device for at least one drive of a conveying device, in particular an extra-low voltage drive. The motor control device has a low-voltage supply interface for the direct connection of the motor control device to a low-voltage line. The low-voltage device interface is formed by piercing technology so that the connection to the low-voltage line takes place without interruption.

According to the present disclosure, the object is furthermore achieved by a system, comprising a low-voltage line and at least one motor control device for at least one drive of a conveying device, the at least one motor control device being connected to the low-voltage line by piercing technology. A connection of the motor control device to the low-voltage line without interruption is thus provided, the low-voltage line conducting a low voltage above an extra-low voltage.

The basic idea is to supply the motor control device or the motor controller directly with low voltage, for which purpose the motor control device has the low-voltage supply interface. The advantages of a low-voltage supply are thus maintained, which allow the supply of a plurality of drives via one supply line, so that the number of parallel supply branches can be minimized, in particular even completely avoided. Due to the connection of the motor control device to the low-voltage line by piercing technology, there is no power loss due to transition resistances in one branch, i.e. in the area of the electrical connection, which ensures the maximum extension of the conveying device or the system. The number of drives connected to the low-voltage line can thus be further increased.

The system thus allows a larger extension of an intralogistics system without the need to route an additional low-voltage supply in parallel or to install fuse protections.

The drives are in particular an extra-low voltage drive, i.e. a drive which is operated or supplied with an extra-low voltage. More precisely, the drives may be roller motors, belt drum motors or external small drives used to drive rollers of the conveying device.

Basically, an extra-low voltage is a voltage of up to 50 Volt alternating current (VAC) or 120 Volt direct current (VDC).

The drives can thus be supplied with a voltage of up to 50 Volt alternating current (VAC) or 120 Volt direct current (VDC), whereas the motor control device is directly supplied with a low voltage via the low-voltage supply interface. The low voltage is above the extra-low voltage.

Therefore, the motor control device which is supplied with the low voltage, and the drive which is driven by the motor control device an is supplied with the extra-low voltage, are operated with different voltages.

In addition to the low-voltage supply interface, via which the motor control device is connected to the low-voltage line for achieving a low voltage, the motor control device also has at least one output interface for the drive, in particular an extra-low voltage output interface via which the drive is supplied with the extra-low voltage.

It is advantageous if the output voltage is variable to thus adjust the speed of the motor. Furthermore, it is advantageous if the polarity of the output voltage can be reversed to thus change the direction of rotation of the motor.

Furthermore, the output interface may have a monitoring function, in particular a current monitoring. Furthermore, the output interface may comprise one or more communication interfaces which are in particular set up to control the motor or to read out the rotational angle and/or the rotational speed of the motor.

To obtain a higher accuracy as to the rotational angle and the rotational speed of the motor, the connection interface can be configured for connecting step motors.

According to one aspect, the motor control device has at least one DC output interface which is set up to be connected to the at least one drive of the conveying device. The output interface, in particular the extra-low voltage output interface, is thus configured as a DC output interface so that the drive is supplied with a direct voltage.

The low-voltage line can also provide a direct voltage as supply voltage, so that the motor control device is also supplied with a low voltage. In this respect, the motor control device does not have to include an integrated AC/DC converter.

However, it may be provided that an AC/DC converter is arranged upstream of the conveying device, the low-voltage line branching off from the AC/DC converter.

The use of a DC low-voltage supply allows a simple recovery of braking energy, i.e. recuperation of energy, which can improve the efficiency of the conveying device. The recovery can take place into the DC mains, i.e. the supply mains to be consumed at another point. Alternatively or additionally, the recovered energy can be temporarily stored.

Furthermore, the DC voltage supply allows the integration into a DC microgrid. In this way, renewable energy such as solar energy or energy temporarily stored in batteries can also easily be used for the supply.

In one preferred embodiment, the low-voltage supply interface is designed for a low voltage above an extra-low voltage, the extra-low voltage being up to 50 V alternating current or 120 V direct current. Particularly preferably, the low voltage is set to a rated voltage of 500 V to 800 V direct current, in particular a rated voltage of 600 V direct current, or a rated voltage of 100 V to 400 V alternating current, in particular 240 V alternating current. As already mentioned above, a higher output is provided under identical installation conditions due to the low voltage, which allows a larger number of drives to be supplied.

It may be provided that the motor control device has at least one communication interface, in particular a fieldbus terminal and/or at least one sensor terminal. The sensor terminal may be configured as an IO-Link. The communication interface allows communication with the motor control device. The motor control device can in particular have a fieldbus terminal configured as a fieldbus input and a fieldbus terminal configured as a fieldbus output. This allows as simple and quick connection of different motor control devices with each other, so that data can also be exchanged between the motor control devices. This is particularly important if a plurality of motor control devices according to the present disclosure are used within the system or the conveying device. The fieldbus may be an Ethernet-based fieldbus such as ProfiNet, Ethernet/IP, OPC/UA FLC.

A sensor may be connected via the at least one sensor terminal to obtain and further process, in particular exchange information via the sensor. The sensor terminal can be based on an AS interface (Actuator-Sensor Interface—“ASI”), thus a standard for fieldbus communication.

Alternatively, the sensor terminal may be configured as an IO-Link or be designed for digital sensors, in particular for describing the exact HI-/LO signal behavior, i.e. in accordance with the behavior of the IEC 61131 standard.

The motor control device comprises a base body and a piercing adapter which is formed separately from the base body and is intended to pierce the low-voltage line. The safety of contact is thus created even if the base body is lifted, as the live part is not exposed. Accordingly, the base bodies can also be removed during operation.

Furthermore, the use of a separate piercing adapter facilitates the accurate positioning and thus the connection of the motor control device to the low-voltage line. This makes it easier to connect the low-voltage line as initially only the adapter can be used for the precise positioning and piercing of the line, after which the base body can then be placed onto the piercing adapter.

In addition, the adapter allows the low-voltage line to be pierced under voltage so that the system can be extended during operation. To this end, the adapter provides the required distances allowing a touch-proof installation, the contacts of the piercing adapter being also configured to be touch-proof.

Due to the adapter, the motor control device is further configured to be adaptable, as the motor control device can basically be coupled to different types of low-voltage lines, in particular regarding the diameter and/or the shape of the low-voltage line. It is only necessary to choose the appropriate adapter to be able to pierce the low-voltage line. The adapter has a standardized interface via which the adapter is electrically coupled to a receptacle on the base body.

The base body has a receptacle for the piercing adapter, the receptacle and/or the piercing adapter being configured in accordance with the poka-yoke principle, so that the piercing adapter can only be received in a defined manner by the receptacle. The input interface via which the adapter is electrically connected may be provided in the receptacle in the base body. Furthermore, the adapter may be configured such that the low-voltage line is only pierced in a defined manner by piercing technology. This is particular important if the low-voltage line is configured to be unsymmetrical. The poka-yoke principle ensures that the low-voltage line is pierced with reverse polarity protection or correct polarity and that the adapter and the base body are coupled to each other with reverse polarity protection or correct polarity.

The motor control device also includes a base having a guide for the low-voltage line. The base is also adapted to be coupled to the base body. This configuration of the motor control device facilitates the direct connection to the low-voltage line and simplifies the piercing thereof. Due to the predetermined guiding of the low-voltage line, an unintentional incorrect piercing which involves potential risks can be avoided. The guide on the base can in particular be configured such that the low-voltage line can only be received in a defined manner. The base may also be configured in accordance with the poka-yoke principle, so that the low-voltage line can only be received by the base in a determined manner and/or the piercing adapter can only be coupled to the base in a predefined manner. The guide can also cooperate with the piercing adapter to pierce the low-voltage line.

The piercing adapter can be coupled to the base to thus simultaneously mechanically secure the pierced low-voltage line, for example by clamping.

The base and/or the piercing adapter are/is configured such that the low-voltage line may be a round conductor or a flat ribbon cable having in particular a different diameter or size. The base body can be used irrespective of the type of the low-voltage line, as at most the base and/or the piercing body are/is to be adapted.

The low voltage used is preferably a direct voltage, in particular a direct voltage of 500 V to 800 V, preferably 600 V. As already discussed above, the use of such a direct voltage permits a subsequent connection of the system to a DC microgrid and the use of renewable energies, in particular solar energies. The use of a DC low voltage also facilitates the recovery of conveying energies into the DC mains. Alternatively, the system can however also be operated with an alternating voltage in the low-voltage range.

According to one embodiment, the system has at least one connection module which is configured separately from the motor control device. The at least one connection module is directly coupled to the low-voltage line using piercing technology. In addition, the at least one connection module is connected to the at least one motor control device to supply the latter with the supply voltage. It is in particular provided that each motor control device has one connection module assigned thereto. This configuration allows a higher flexibility in the design of the intralogistics system. Due to the separated connection modules, the motor control devices do not have to be directly fastened to the low-voltage line, rather, they may have a direct contact to the low-voltage supply via the connection modules. The motor control devices can in particular be placed in easily accessible locations, the low-voltage line being however not openly accessible.

Basically, the connection module thus ensures that the at least one motor control device is connected to the low-voltage line using piercing technology, namely indirectly.

If no connection module is provided, the at least one motor control device can be directly connected to the low-voltage line using piercing technology. To this end, the motor control device has the low-voltage supply interface by means of which the motor control device is directly connected to the low-voltage line. A further aspect of the present disclosure provides that the system comprises a plurality of motor control devices each connected to the low-voltage line using piercing technology, and/or a plurality of drives per motor control device, in particular 4 drives per motor control device. The system according to the present disclosure thus allows the supply of an entire conveying device via one single low-voltage line, without further separate lines and/or fuse protections being necessary.

The system, for example the conveying device, preferably comprises a total of more than 15 drives.

A further aspect of the present disclosure provides that the system comprises at least one buffer capacitor which is set up to temporarily store recuperation energy. The energy costs can thus be reduced as it is possible to temporarily store recovered braking energy and to use it at a later time. The buffer capacitor may be integrated into the motor control device. It is also conceivable that the buffer capacitor is configured separately from the motor control device.

Alternatively, the recovered energy can be directly used by other motors.

According to a preferred embodiment, the low-voltage line is configured as a flat ribbon cable and/or as a hybrid cable for the simultaneous voltage and data supply. By combining the voltage and data supply, less individual lines are required, which simplifies the installation and maintenance of the system. The flat ribbon cables are particularly suitable for the piercing technology as the position of the individual cores can be precisely determined in a mechanical manner, as a result of which they can be precisely contacted by the piercing pins. Furthermore, due to the unsymmetrical configuration of the line, the polarity of the individual cores upon piercing of the device is unambiguous.

However, as flat ribbon cables are specific lines and may thus be expensive, the use of round cables is of course also possible. When using round cables and contacting by means of piercing technology, it is preferably initially provided that the line is stripped, i.e. the outer insulation is removed so that the individual cores of the line can be pierced.

Alternatively, the low-voltage line may simultaneously be configured as a data line so that a data transmission is modulated upon the voltage supply. This also reduces the number of required cables, so that the installation and setup are clearer. This is generally referred to as power-line technology. A corresponding injector may be provided, via which the data is modulated thereon. The injector may be part of an AC/DC converter or may generally be configured as a separate component.

The at least one motor control device may have an addressing. This can be used for communication by fieldbus technology. The address may be set on the motor control device itself, for example via a programming interface or a coding switch such that flexible addressing is possible.

Alternatively, addressing may also take place in that the at least one motor control device is provided at a defined position in the system, in particular a specific position of the conveying device. The at least one motor control device can then have a fixed address assigned to a specific position. For example, an apparatus identifies its adjacent apparatus as the apparatuses in one chain are assigned to unique positions.

The address may also be provided on the at least one motor control device so as to be (machine) readable, for example in the form of a QR code or an RFID tag. Each motor control device has a specific and unique ID (UID: unique ID) assigned thereto, which corresponds to a logical address. This logical address in turn corresponds to a physical position in the system. The respective assignment can be realized via a separated device such as a computer or a smartphone.

The address may basically be a MAC address in an Ethernet-based system.

If the position of the at least one motor control device is unknown or flexible, it may be provided that a position is measured, for example by means of a transit time measurement, in which the signal transit time of a signal from an emitter to the motor control device is measured.

Basically, it may be provided that the at least one motor control device identifies itself in an independent manner when communication is set up by the transmission of address information.

### BRIEF DESCRIPTION OF THE DRAWINGS

Further features and advantages of the present disclosure will become apparent from the description below and from the drawings to which reference is made and in which:

FIG. 1 shows an exploded view of a system according to the invention comprising a motor control device according to the present disclosure, the system having a low-voltage line configured as a flat ribbon cable;

FIG. 2 shows an exploded view of a system according to the present disclosure comprising an alternative embodiment of the motor control device according to the present disclosure, a round cable being provided instead of the flat ribbon cable;

FIG. 3 shows a conveying device comprising a system according to the present disclosure having a motor control device according to the present disclosure for drives of the conveying device;

FIG. 4 shows a system according to the present disclosure comprising a plurality of motor control devices, connection modules being used for the connection to the low-voltage line;

FIG. 5 shows a conveying device used in the intralogistics which includes the system according to the present disclosure shown in FIGS. 4; and

FIG. 6 shows the structure of a system according to the present disclosure comprising a modulated data supply.

### DETAILED DESCRIPTION OF THE DRAWINGS

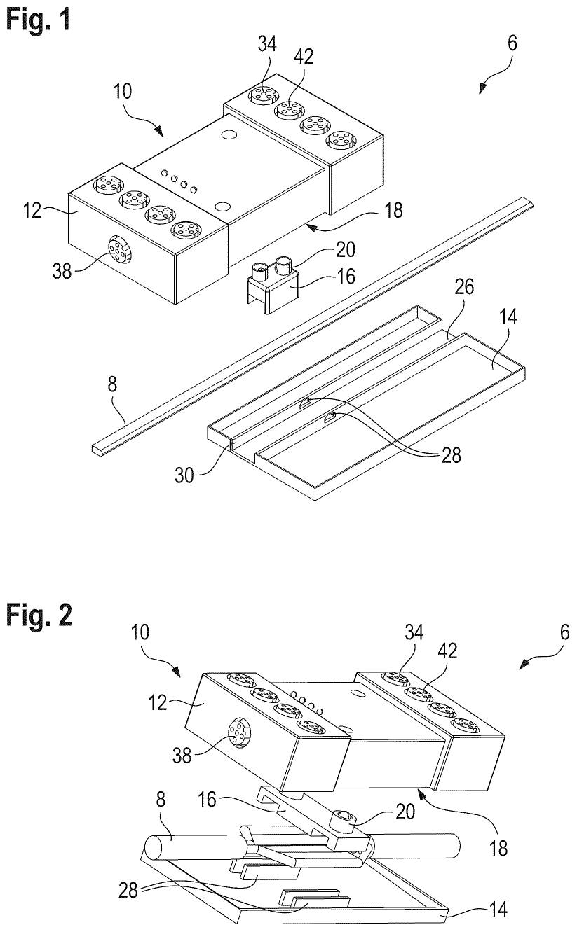

FIG. 1 shows a system 6 according to the invention, comprising a low-voltage line 8 and a motor control device 10 according to the invention which can be coupled to the low-voltage line 8.

The motor control device 10 has a base body 12, a base 14 and a piercing adapter 16.

The base body 12 and the base 14 are configured so as to be able to be coupled to each other so that a detachable mechanical connection can be obtained between the base body 12 and the base 14.

In the assembled state, the piercing adapter 16 is received by the base body 12 which, to this end, is in particular hood-shaped and has a receptacle 18 and by means of which the piercing adapter 16 can be connected via an interface 20.

The receptacle 18 and/or the interface 20 can be configured according to the poka-yoke principle so that the piercing adapter 16 can only be received in a defined manner by the receptacle 18.

In the embodiment shown, the low-voltage line 8 is configured as a flat ribbon cable by means of which the motor control device 10 is directly connected using the piercing adapter 16.

In this respect, the piercing adapter 16 in this embodiment constitutes a low-voltage supply interface 22 of the motor control device 10, via which the motor control device 10 is directly electrically connected by piercing technology. In this respect, the connection to the low-voltage line 8 takes place without interruption.

The base 14 has a guide 26 which receives the low-voltage line 8.

Furthermore, clamping points 28 are provided on sidewalls 30 of the guide 26, via which the piercing adapter 16 can be held in a clamped manner by the guide 26 of the base 14.

The base 14 and the piercing adapter 16 can also be configured in accordance with the poka yoke principle so that the piercing adapter 16 can only be coupled in a specific way to the base 14, in particular the clamping points 28.

The motor control device 10 is connected to the low-voltage line 8 in that first the low-voltage line 8 is positioned in the guide 26 of the base 14. The piercing adapter 16 is then placed at the correct position. If pressure is applied to the piercing adapter 16, the piercing adapter 16 pierces the low-voltage line 8, as a result of which a direct electrical contact is established between the motor control device 10 and the low-voltage line 8, more specifically via the piercing adapter 16. At the same time, the piercing adapter 16 is held in a clamped manner in the guide 26 by means of the clamping points 28, so that it is not unintentionally detached. The base body 12 is finally placed onto the base 14, the receptacle 18 in the base body 12 being coupled to the interface 20 of the base 14 in that the base body 12 receives the piercing adapter 16.

The low-voltage line 8 can also be pierced due to the piercing adapter 16 when the low-voltage line 8 is under voltage. To this end, the piercing adapter 16 has touch-proof contacts which are positioned so as to have the required distances for piercing the correct core of the low-voltage line 8 designed as a flat ribbon cable. This is in particular possible as the positions of the individual cores in the flat ribbon cable are precisely defined in an mechanically manner.

FIG. 2 shows an alternative embodiment in which the low-voltage line 8 is designed as a round cable.

In this respect, the piercing adapter 16 is configured differently to electrically contact the low-voltage line 8 designed as a round cable by piercing technology.

In particular, the low-voltage line 8 designed as a round cable is first partially stripped or dismantled to expose the individual cores which are then contacted by means of the piercing adapter 16.

This variant embodiment differs from the previous variant in that the clamping points 28 are not formed on sidewalls of a guide, but on projections onto which the piercing adapter 16 is placed.

In addition, the clamping points 28 can be configured as double projections so that the individual cores of the low-voltage line 8 designed as a round cable can be securely positioned to simultaneously ensure a correct positioning of the piercing adapter 16.

In the variant embodiment shown, the piercing adapter 16 has an interface 20 of a different design compared to the first variant embodiment.

It can be provided that the piercing adapters 16 always have a uniform interface so that they can be used with the same base body 12.

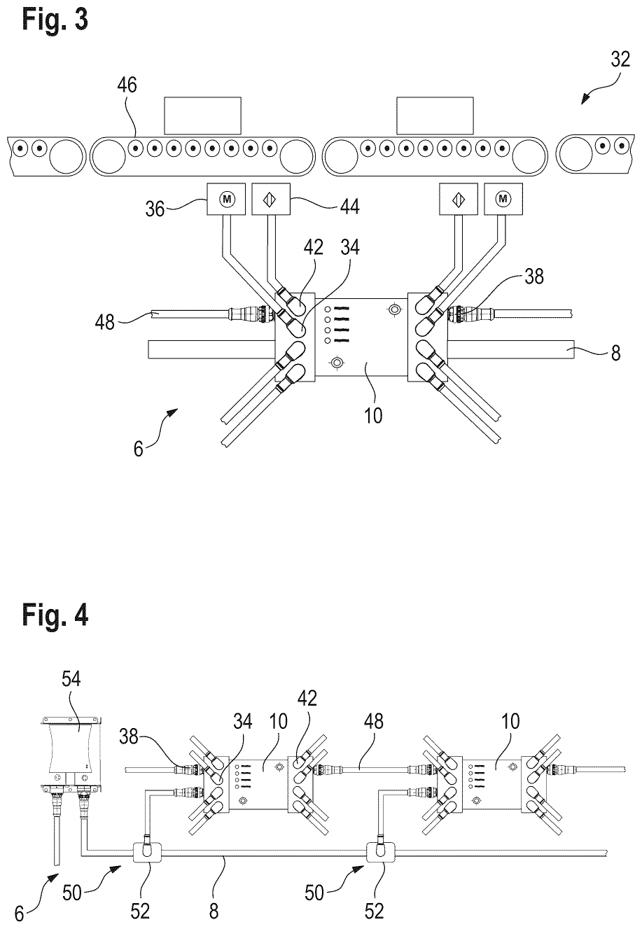

For integration into a conveying device 32, which is shown in FIG. 3, the motor control device 10 also has an output interface 34 for a drive 36, a communication terminal 38, in particular a fieldbus terminal, and a sensor terminal 42 for a sensor 44. The drive 36 can in particular be an extra-low voltage drive, i.e. a drive which is operated or supplied with an extra-low voltage, i.e. with a voltage of up to 50 Volt alternating current (VAC) or 120 Volt direct current (VDC). In contrast thereto, the motor control device 10 is connected to the low-voltage line 8 to which a low voltage is applied which is higher than the extra-low voltage, i.e. higher than the 50 Volt alternating current (VAC) or 120 Volt direct current (VDC). The low voltage is for example set to a rated voltage of 500 V to 800 V direct current, in particular 600 V direct current, or a rated voltage of 100 V to 400 V alternating current, in particular 110 V to 240 V alternating current.

The low voltage may thus be a direct voltage so that the output interface 34 is configured so as to supply the drive 36 of the conveying device 32 with direct voltage.

FIG. 3 shows that the conveying device 32 has the system 6 which comprises the low-voltage line 8 and at least one motor control device 10 to which a plurality of drives 36 are connected via the appropriate output interfaces 34.

The conveying device 32 further comprises roller paths 46 which are driven by the drives 36. As shown in FIG. 3, each roller path 46 has its own drive 36 and an own sensor 44.

Basically, the sensors 44 can monitor the state of the conveying device 32, in particular of components of the conveying device 32.

The motor control device 10 receives the driving commands via the communication terminal 38. It is also possible to transmit information of the sensors 44 via the communication terminal 38.

In this respect, a data line 48, in particular a fieldbus line is connected to the communication terminal 38.

To this end, further motor control devices 10 can be connected to the fieldbus so that the motor control devices 10 communicate with each other via the fieldbus. To this end, the motor control devices 10 have a communication terminal 38 configured as a fieldbus inlet, and a communication terminal 38 configured as a fieldbus outlet.

Ethernet-based fieldbuses are typically used. Alternatively or additionally, an actor/sensor interface (ASi) can be used.

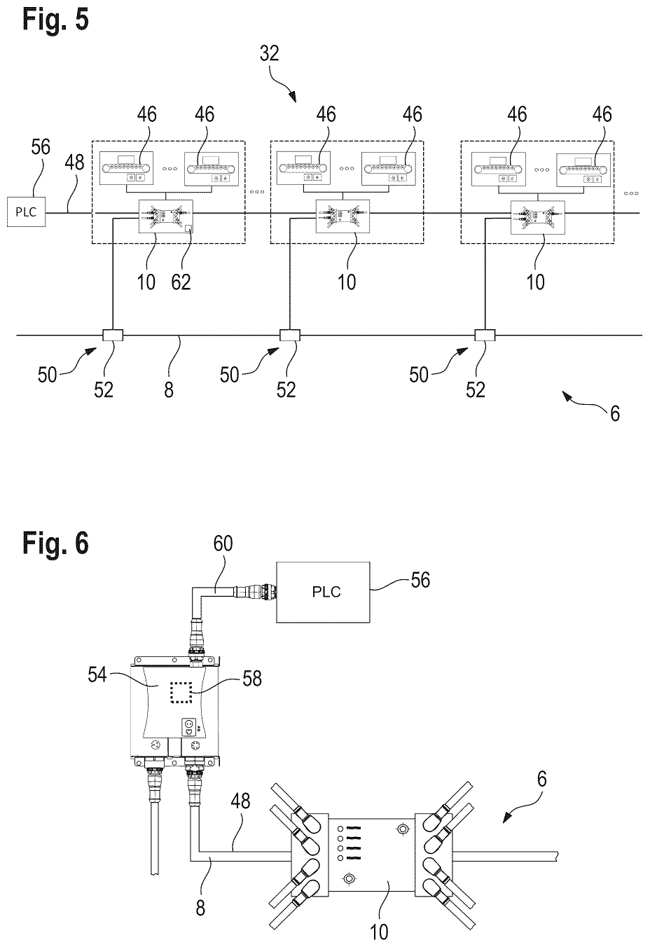

In the embodiment shown in FIGS. 4 and 5, the motor control devices 10 are connected to each other by the separated data line 48, in particular the fieldbus line. This applies in a similar way to the embodiment according to FIG. 3, even if only one motor control device 10 is shown there.

The data line 48 is required for addressing individual motor control devices 10. An exact addressing is in particular required in large intralogistics systems such as shown in FIG. 5, for example. Here, individual sections are each composed of a motor control device 10 and a plurality of roller paths 46 along with the associated drives 36 and sensors 44. For a better overview, these individual sections are marked with dashed boxes.

There are different possibilities to address the motor control device 10 via a data line 48. In the simplest case, an address is set directly on the motor control device 10. This can be carried out using mechanical switches, but also via a programming interface.

A further possibility is to assign a specific position in the system 6 or the conveying device 32 to a motor control device 10, the motor control devices 10 having a fixed address for this purpose, which is assigned to one position. For example, the MAC address which is unique in Ethernet-based systems, is for example suitable as an address. To make operation easier, this address can be printed on the motor control device 10 in a readable form or can be retrieved using machine-readable markings such as a QR code or a RFID tag. In machine-readable markings, the association between the positions in a control program and the real motor control device 10 takes place using an additional apparatus.

Alternatively, the motor control device 10 can also be configured such that it identifies itself. The motor control device 10 would then communicate its address and thus make itself known to a central control system.

It is also possible to measure the position of a motor control device 10 in the system 6. The position of the motor control device 10 is then determined via signal transit times between the signal source and the motor control device 10, as a result of which a position can be assigned to the motor control device 10.

According to an alternative embodiment, the direct connection of the motor control device 10 and the low-voltage line 8 can also be established by a separately formed connection module 50, as shown in FIGS. 4 and 5.

The connection module 50 comprises the piercing adapter 16 which is received in a separate housing 52 of the connection module 50.

In particular, exactly one connection module 50 is assigned to each motor control device 10, via which the motor control device 10 is electrically connected to the low-voltage line 8.

FIG. 4 also shows an AC/DC converter 54. The latter allows an AC power supply for the system 6 by converting the alternating current into direct current. The motor control device 10 is thus further operated with direct current.

The data line 48 is routed parallel to the voltage supply, via which communication between the motor control devices 10 and with a central controller 56 takes place. In FIG. 5, the central controller 56 is referred to as “Programmable Logic Controller”—PLC, from which the data line 48 is connected to the motor control devices 10.

The central controller 56 may be a stored-program controller (SPS). Alternatively to the SPS, it is also possible to use industrial PCs, Edge-Gateways (EGW) or a terminal to another control system.

According to one embodiment, the data line 48 can be integrated into the low-voltage line 8 such that no separate data connection is required. A hybrid cable can be provided for this purpose.

Basically, a plurality of drives 36 which are provided for each motor control device 10 can be present in a large system 6 or a large conveying device 32, as shown in FIG. 5. The drives 36 can be connected in parallel so that the plurality of drives 36 is supplied with energy via the drives 36.

According to an alternative variant as shown in FIG. 6, the AC/DC converter 54 can include an integrated power-line injector 58. Alternatively, the power-line injector 58 can be provided separately from the AC/DC converter 54, in particular if the system 6 is a DC voltage system in which no AC/DC converter 54 is provided.

Generally, data transmission can thus be modulated upon the voltage supply so that the separate data line 48 is not required. In other words, the low-voltage line 8 then simultaneously forms the data line 48, as shown in FIG. 6.

FIG. 6 also shows that in this case, the central controller 56 is connected to the AC/DC converter 54 via a fieldbus connection 60.

Furthermore, in particular if the system 6 is a DC voltage system, it may be provided that the system 6 comprises at least one buffer capacitor 62 which is set up to temporarily store recuperated energy, for example braking energy. As shown in FIG. 5, the buffer capacitor 62 can be arranged in the motor control device 10 itself or separately therefrom. The buffer capacitor 62 can generally be provided in each of the components of the system 6.

1. A motor control device for at least one drive of a conveying device, the motor control device having a low-voltage supply interface for a direct connection of the motor control device to a low-voltage line, the low-voltage supply interface being formed by piercing technology so that the connection to the low-voltage line takes place without interruption.

2. The motor control device according to claim 1, wherein the motor control device has at least one DC output interface which is set up to be connected to the at least one drive of the conveying device.

3. The motor control device according to claim 1, wherein the low-voltage supply interface is designed for a low voltage above an extra-low voltage, the extra-low voltage being up to 50 Volt alternating current or 120 Volt direct current.

4. The motor control device according to claim 1, wherein the low-voltage supply interface is designed for a rated voltage of 500 V to 800 V direct current or a rated voltage of 100 V to 400 V alternating current.

5. The motor control device according to claim 1, wherein the motor control device has at least one communication terminal.

6. The motor control device according to claim 5, wherein the at least one communication terminal is a fieldbus terminal.

7. The motor control device according to claim 1, wherein the motor control device has at least one sensor terminal.

8. The motor control device according to claim 1, wherein the motor control device comprises a base body and a piercing adapter formed separately from the base body, which is set up to pierce the low-voltage line.

9. The motor control device according to claim 8, wherein the base body has a receptacle for the piercing adapter, the receptacle and/or the piercing adapter being configured in accordance with the poka-yoke principle, so that the piercing adapter can only be received in a defined manner by the receptacle.

10. The motor control device according to claim 1, wherein the motor control device includes a base having a guide for the low-voltage line, and the base being adapted to be coupled to a base body.

11. A system comprising a low-voltage line and at least one motor control device for at least one drive of a conveying device, the at least one motor control device being connected to the low-voltage line by piercing technology, so that the connection of the motor control device to the low-voltage line takes place without interruption, and the low-voltage line conducting a low voltage above an extra-low voltage.

12. The system according to claim 11, wherein the low voltage is a direct voltage.

13. The system according to claim 11, wherein the low voltage is a direct voltage of 500 V to 800 V.

14. The system according to claim 11, wherein the system has at least one connection module which is formed separately from the motor control device, the at least one connection module being directly connected to the low-voltage line by piercing technology, and the connection module being connected to the at least one motor control device to supply the motor control device with a supply voltage.

15. The system according to claim 11, wherein the system comprises a plurality of motor control devices which are each connected to the low-voltage line by piercing technology.

16. The system according to claim 11, wherein the system comprises a plurality of drives per motor control device.

17. The system according to claim 11, wherein the system comprises four drives per motor control device and/or wherein the system comprises more than fifteen drives in total.

18. The system according to claim 11, wherein the system comprises at least one buffer capacitor which is set up to temporarily store recuperated energy.

19. The system according to claim 11, wherein the low-voltage line is configured as a flat ribbon cable and/or a hybrid cable for a simultaneous voltage and data supply.

20. The system according to claim 11, wherein the low-voltage line simultaneously forms a data line so that a data transmission is modulated upon a voltage supply.
